(19) United States
(12) Patent Application Publication
(10) Pub. No.: US 2026/0191059 A1
(43) Pub. Date: Jul. 2, 2026

(54) SEMICONDUCTOR PACKAGE

(71) Applicant: SAMSUNG ELECTRONICS CO., LTD., Suwon-si (KR)

(72) Inventors: Minjong WANG, Suwon-si (KR); Hongjin KIM, Suwon-si (KR); Eunhye LEE, Suwon-si (KR)

(73) Assignee: SAMSUNG ELECTRONICS CO., LTD., Suwon-si (KR)

(21) Appl. No.: 19/416,420

(22) Filed: Dec. 11, 2025

(30) Foreign Application Priority Data
Dec. 26, 2024 (KR) 10-2024-0196913

(51) Int. Cl. H10W 70/654; H10W 70/695; H10W 72/00; H10W 72/30; H10W 90/00

(52) U.S. Cl. CPC H10W 70/654; H10W 72/342; H10W 72/884; H10W 90/734; H10W 90/754; H10W 70/695

(57) ABSTRACT

A semiconductor package includes a package substrate having a chip mounting region, the package substrate including at least one insulating layer, upper circuit wirings having a first wiring and a second wiring that respectively extend on the at least one insulating layer, and an upper protective layer covering the upper circuit wirings on the at least one insulating layer and having a first opening and a second opening that respectively expose first portions of the first wiring and the second wiring; a semiconductor chip disposed on the chip mounting region of the package substrate and having a plurality of chip pads; and a conductive adhesive film attaching the semiconductor chip to the package substrate, and disposed in the first opening and the second opening to contact the first portions of the first wiring and the second wiring, respectively, to electrically connect the first wiring and the second wiring.

### PRIORITY STATEMENT

This application claims priority under 35 U.S.C. § 119 to Korean Patent Application No. 10-2024-0196913, filed on Dec. 26, 2024 in the Korean Intellectual Property Office (KIPO), the contents of which are herein incorporated by reference in their entirety.

### BACKGROUND

### 1. Field

Example embodiments relate to a package substrate, a semiconductor package and a method of manufacturing the semiconductor package. More particularly, example embodiments relate to a semiconductor package including a semiconductor chip attached to a package substrate by an adhesive film and a method of manufacturing the same.

### 2. Description of the Related Art

In manufacturing a semiconductor package, a semiconductor chip may be attached to a package substrate using an adhesive film, and bonding wires may be used to connect chip pads of the semiconductor chip and bond fingers of the package substrate. Circuit patterns may be provided on an uppermost insulating layer of the package substrate to be electrically connected to the semiconductor chip, and an upper protective layer may be coated on the uppermost insulating layer to cover the circuit patterns. Some patterns of the circuit patterns may be merged with each other in another circuit layer below the uppermost insulating layer through a connection via. However, due to limitations in the number of circuit layers and a routing space, there is a problem that routing design is not easy and signal characteristics deteriorate.

### SUMMARY

Example embodiments provide a semiconductor package having a structure capable of improving electrical characteristics.

According to example embodiments, a semiconductor package includes a package substrate having a chip mounting region, the package substrate including at least one insulating layer, upper circuit wirings having a first wiring and a second wiring that respectively extend on the at least one insulating layer, and an upper protective layer covering the upper circuit wirings on the at least one insulating layer and having a first opening and a second opening that respectively expose first portions of the first wiring and the second wiring; a semiconductor chip disposed on the chip mounting region of the package substrate and having a plurality of chip pads; and a conductive adhesive film attaching the semiconductor chip to the package substrate, and disposed in the first opening and the second opening to contact the first portions of the first wiring and the second wiring, respectively, to electrically connect the first wiring and the second wiring to each other.

According to example embodiments, a semiconductor package includes a plurality of insulating layers having a chip mounting region; upper circuit wirings having a first wiring and a second wiring that respectively extend on an uppermost insulating layer among the plurality of insulating layers and at least one signal wiring that extends between the first wiring and the second wiring; an upper protective layer covering the upper circuit wirings on the uppermost insulating layer and having a first opening and a second opening that respectively expose first portions of the first wiring and the second wiring within the chip mounting region, and a recess that expose a portion of the at least one signal wiring outside the chip mounting region; a plating pattern disposed on the portion of the at least one signal wiring exposed within the recess; a semiconductor chip disposed within the chip mounting region on the upper protective layer and having a plurality of chip pads; a conductive adhesive film within the chip mounting region and attaching the semiconductor chip to the package substrate, wherein the conductive adhesive film is disposed in the first opening and the second opening to contact the first portions of the first wiring and the second wiring, respectively, to electrically connect the first wiring and the second wiring to each other; and a bonding wire electrically connecting one chip pad of the plurality of chip pads to the plating pattern.

According to example embodiments, a semiconductor package includes a package substrate having a chip mounting region, the package substrate including a plurality of insulating layers, upper circuit wirings having a first wiring and a second wiring that respectively extend on an uppermost insulating layer among the plurality of insulating layers and at least one signal wiring that extends between the first wiring and the second wiring, and an upper protective layer covering the uppermost insulating layer and having first and second openings that expose first portions of the first and second wirings, respectively, and a recess that expose second portions of the first and second wirings, respectively; plating patterns formed on the second portions of the first and second wirings exposed within the recess; a semiconductor chip on the upper protective layer and having a plurality of chip pads; a conductive adhesive film within the chip mounting region and attaching the semiconductor chip to the package substrate, wherein the conductive adhesive film is disposed in the first opening and the second opening to contact the first portions of the first wiring and the second wiring, respectively, to electrically connect the first wiring and the second wiring to each other; and bonding wires electrically connecting the chip pads to the plating patterns.

According to example embodiments, a semiconductor package may include a semiconductor chip attached to an upper surface of a package substrate by a conductive adhesive film. The package substrate may include upper circuit wirings including a first wiring and a second wiring extending on an uppermost insulating layer, and an upper protective layer covering the uppermost insulating layer and having first and second openings that expose first portions of the first and second wirings respectively.

The conductive adhesive film may contact the first portions of the first and second wirings exposed by the first and second openings respectively, so that the first wiring and the second wiring, which are provided as power wirings or ground wirings, can be merged/connected with each other by the conductive adhesive film. That is, the first and second wirings on the uppermost insulating layer may be merged/connected by the conductive adhesive film that is attached to the package substrate, instead of another circuit layer inside the package substrate. Accordingly, electrical signal characteristics such as signal integrity (SI) and power integrity (PI) may be improved. Further, since the first and second wirings do not need to be merged with each other in different circuit layers below the uppermost insulating layer through connection vias, the circuit routing may be easily designed.

### BRIEF DESCRIPTION OF THE DRAWINGS

Example embodiments will be more clearly understood from the following detailed description taken in conjunction with the accompanying drawings. FIGS. 1 to 15 represent non-limiting, example embodiments as described herein.

FIG. 1 is a plan view illustrating a semiconductor package in accordance with example embodiments.

FIG. 2 is a cross-sectional view taken along the line A1-A1′ in FIG. 1.

FIG. 3 is a cross-sectional view taken along the line B1-B1′ in FIG. 1.

FIG. 4 is a cross-sectional view taken along the line C1-C1′ in FIG. 1.

FIG. 5 is a plan view illustrating a conductive adhesive film bonded on the package substrate of FIG. 1.

FIGS. 6 to 15 are views illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings.

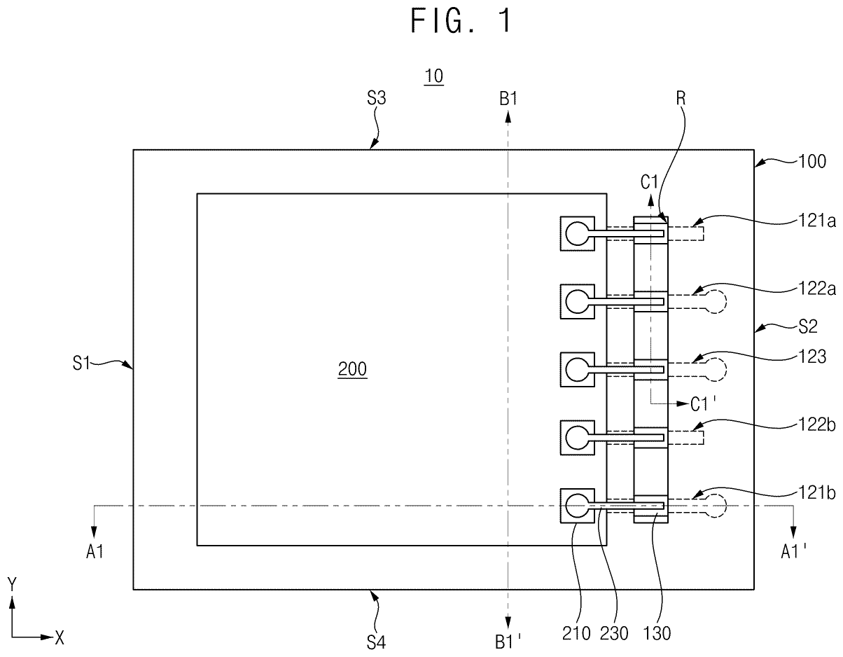

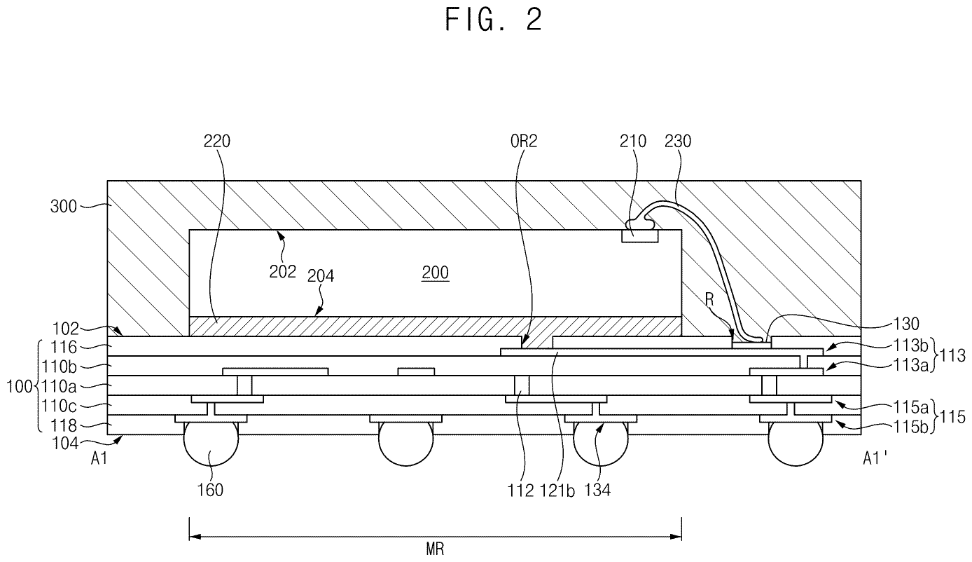

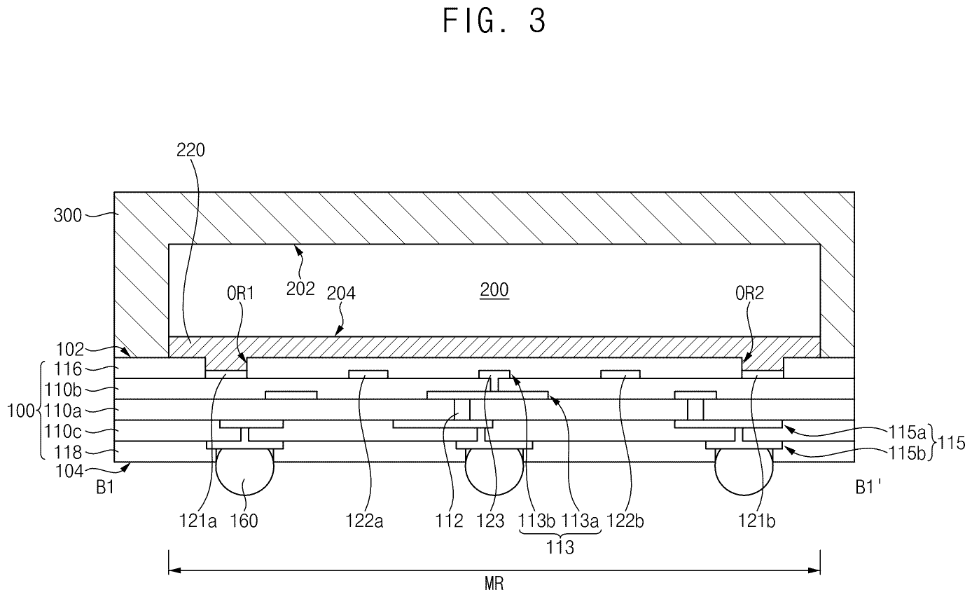

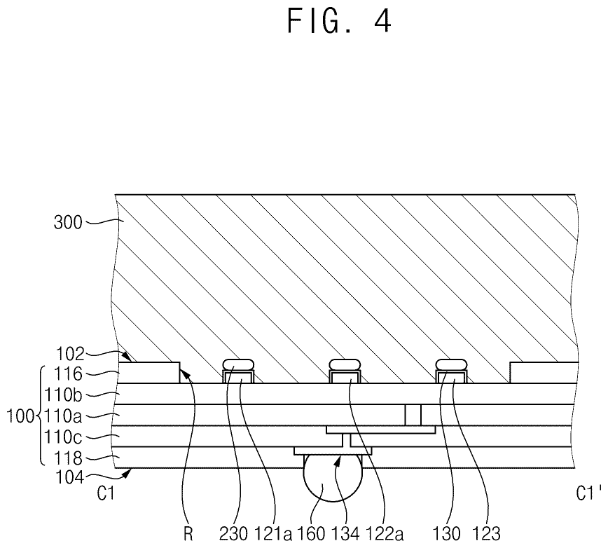

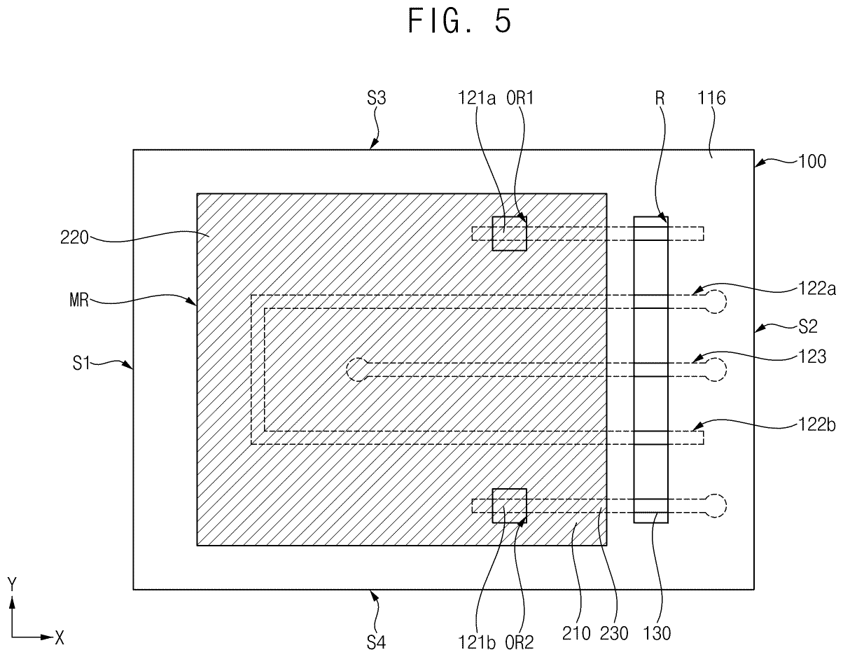

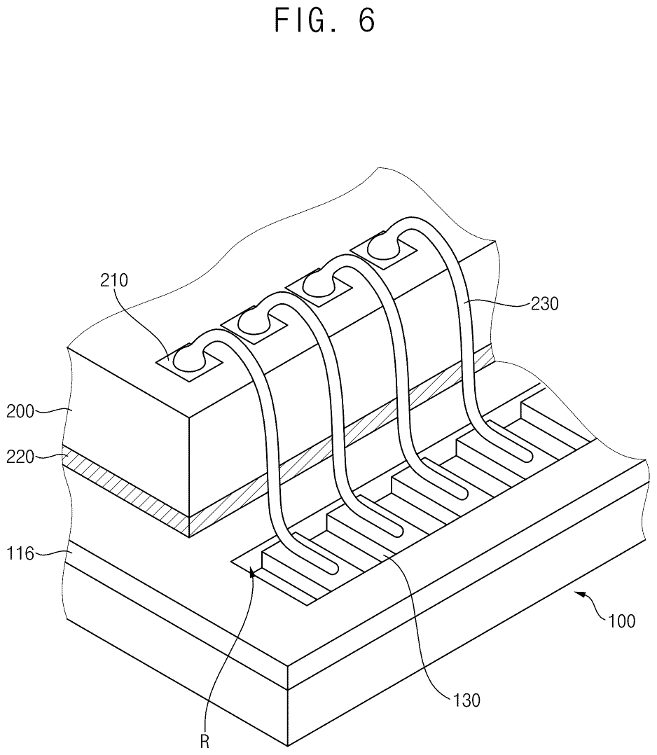

FIG. 1 is a plan view illustrating a semiconductor package in accordance with example embodiments. FIG. 2 is a cross-sectional view taken along the line A1-A1′ in FIG. 1. FIG. 3 is a cross-sectional view taken along the line B1-B1′ in FIG. 1. FIG. 4 is a cross-sectional view taken along the line C1-C1′ in FIG. 1. FIG. 5 is a plan view illustrating a conductive adhesive film bonded on the package substrate of FIG. 1. FIG. 6 is a perspective view illustrating a portion of a semiconductor chip mounted on the package substrate of FIG. 1. FIG. 1 is a plan view illustrating the semiconductor package, wherein a molding member in FIGS. 2 to 4 is omitted. FIG. 5 is a plan view illustrating the semiconductor package in FIG. 1, wherein the semiconductor chip in FIGS. 2 to 4 is omitted.

Referring to FIGS. 1 to 6, a semiconductor package 10 may include a package substrate 100, at least one semiconductor chip 200 attached to the package substrate by a conductive adhesive film 220, and a plurality of bonding wires 230. In addition, the semiconductor package 10 may further include a molding member 300 and external connection members 160.

In example embodiments, the package substrate 100 may be a substrate having an upper surface 102 and a lower surface 104 opposite to the upper surface 102. For example, the package substrate 100 may include a printed circuit board PCB such as a core multilayer substrate. The PCB may be a multilayer circuit board having vias and various circuits therein. Alternatively, the package substrate 100 may include a coreless substrate. The package substrate 100 may include wirings therein for electrical connection with the semiconductor chip 200.

The package substrate 100 may include a first side portion S1 and a second side portion S2 extending in a direction parallel to a second direction (Y direction) and opposing each other, and a third side portion S3 and a fourth side portion S4 extending in a direction parallel to a first direction (X direction) perpendicular to the second direction and opposing each other.

The package substrate 100 may have a chip mounting region MR in which the semiconductor chip 200 is mounted. The package substrate 100 may include a plurality of bond fingers that are arranged adjacent to the chip mounting region. The bond fingers may be connected to the wirings respectively. The wirings may extend on the upper surface 102 of the package substrate 100 or within the package substrate 100.

As illustrated in FIGS. 2 to 4, the package substrate 100 may include a plurality of insulating layers 110a, 110b, 110c and wirings 113, 115 provided in the insulating layers respectively.

In particular, the package substrate 100 may include a core layer 110a, an upper insulating layer 110b on an upper surface of the core layer 110a, and a lower insulating layer 110c on a lower surface of the core layer 110a. The upper insulating layer 110b may be provided as an uppermost insulating layer among the plurality of insulating layers 110a, 110b, 110c. The lower insulating layer 110c may be provided as a lowermost insulating layer among the plurality of insulating layers 110a, 110b, 110c.

The package substrate 100 may include a plurality of through vias 112 penetrating the core layer 110a, first upper circuit wirings 113a on the upper surface of the core layer 110a, second upper circuit wirings 113b provided in the upper insulating layer 110b, first lower circuit wirings 115a on the lower surface of the core layer 110a, and second lower circuit wirings 115b provided in the lower insulating layer 110c.

The first upper circuit wirings 113a, the second upper circuit wirings 113b, the first lower circuit wirings 115a, and the second lower circuit wirings 115b may include a data transmission pattern for exchanging electrical data with the semiconductor chip, a power pattern for transmitting driving power to the semiconductor chip, and a ground pattern for electrically grounding the semiconductor chip.

As illustrated in FIG. 5, the second upper circuit wirings 113b may extend on the uppermost insulating layer 110b among the plurality of insulating layers 110a, 110b, 110c. The second upper circuit wirings 113b may include a first wiring 121a and a second wiring 121b that are provided as power wirings through which a power signal is transmitted. The second upper circuit wirings 113b may include a third wiring 122a and a fourth wiring 122b that are provided as ground wirings through which a ground signal is transmitted. The second upper circuit wirings 113b may include a fifth wiring 123 that is provided as a signal wiring through which a data signal is transmitted.

The first wiring 121a and the second wiring 121b may extend in a direction parallel to the first direction (X direction) respectively. The fifth wiring 123 as at least one signal wiring may extend between the first wiring 121a and the second wiring 121b. The third wiring 122a and the fourth wiring 122b may extend in both sides of the fifth wiring 123 in a direction parallel to the extension direction of the fifth wiring 123, respectively. One end portion of the third wiring 122a and one end portion of the fourth wiring 122b may be merged with each other.

Although only a few wirings and circuit patterns are illustrated in the figures, the number, shape, and arrangement of the wirings and the circuit patterns are provided as examples, and it will be understood that example embodiments are not limited thereto.

In example embodiments, the package substrate 100 may include an upper protective layer 116 covering the second upper circuit wirings 113b on the upper surface of the upper insulating layer 110b and a lower protective layer 118 covering the second lower circuit wirings 115b on the lower surface of the lower insulating layer 110c. An upper surface of the upper protective layer 116 may be provided as the upper surface 102 of the package substrate 100, and a lower surface of the lower protective layer 118 may be provided as a lower surface 104 of the package substrate 100.

The upper protective layer 116 may have a recess R, and a first opening OR1 and a second opening OR2 within the chip mounting region MR. The upper protective layer 116 may have a recess R outside the chip mounting region MR.

The first opening OR1 may expose a first portion of the first wiring 121a, and the second opening OR2 may expose a first portion of the second wiring 121b. Diameters (widths) of the first opening OR1 and the second opening OR2 may be greater or smaller than widths of the first wiring 121a and the second wiring 121b. In some embodiments, the first opening OR1 may expose a first portion of the third wiring 122a, and the second opening OR2 may expose a first portion of the fourth wiring 122b. In this case, one end portion of the third wiring 122a and one end portion of the fourth wiring 122b may not be merged but may be spaced apart from each other and may not be electrically connected to each other.

The recess R may extend in the second direction (Y direction) along one side of the chip mounting region MR. The recess R may have a rectangular shape. The recess R may expose a second portion of each of the first to fifth wirings 121a, 121b, 122a, 122b, 123. The second portions of the first to fifth wirings 121a, 121b, 122a, 122b, 123 may be spaced apart from each other in the second direction (Y direction) within the recess R. Each of the second portions of the first to fifth wirings 121a, 121b, 122a, 122b, 123 may extend within the recess R in the first direction (X direction). The second portions of the first to fifth wirings 121a, 121b, 122a, 122b, 123 may be exposed from a bottom surface of the recess R.

The first portions of the first to fourth wirings 121a, 121b, 122a, 122b may be positioned within the chip mounting region MR and may be a specific portion of one end portion of each of the first to fourth wirings or between both end portions of each of the first to fourth wirings. The second portion of the fifth wiring 123 may be positioned outside the chip mounting region MR and may be a specific portion of one end portion of the fifth wiring or between both end portions of the fifth wiring.

Similarly, the lower protective layer 118 may be formed on the lower surface of the lower insulating layer 110c to cover the second lower circuit wirings 115b. At least a portion of the second lower circuit wiring 115b exposed by the lower protective layer 118 may be provided as a lower substrate pad 134. The lower protective layer 118 may cover the entire lower surface of the insulating layers except for the lower substrate pads 134.

For example, thicknesses of the upper protective layer 116 and the lower protective layer 118 may be within a range of 5 μm to 30 μm. The thicknesses of the first to fifth wirings 121a, 121b, 122a, 122b, 123 may be within a range of 5 μm to 30 μm. The upper protective layer 116 and the lower protective layer 118 may include a photosensitive resin such as photo epoxy, and a photosensitive polymer such as photosensitive polyimide (PSPI), photo solder resist (PSR), etc.

In example embodiments, each of the bond fingers may include a plating pattern 130 that covers each of the second portions of the first to fifth wirings 121a, 121b, 122a, 122b, 123 extending within the recess R. The plating pattern 130 may include a first plating pattern and a second plating pattern on the first plating pattern. The first plating pattern may include nickel (Ni), and the second plating pattern may include gold (Au).

In example embodiments, the semiconductor chip 200 may be mounted on the chip mounting region MR of the package substrate 100. The semiconductor chip 200 may be mounted on the package substrate 100 by a wire bonding method. The semiconductor chip 200 may be placed such that a rear surface 204 opposite to a front surface 202 on which chip pads 210 are formed, i.e., an active surface, faces the package substrate 100. The semiconductor chip 200 may have a rectangular shape with four sides when viewed in plan view. The chip pads 210 may be arranged on the front surface 202 of the semiconductor chip 200 to be spaced apart from each other along one side thereof.

The semiconductor chip 200 may be attached to the package substrate 100 by a conductive adhesive film 220. The chip pads 210 of the semiconductor chip 200 may be electrically connected to the bond fingers of the package substrate 100 by bonding wires 230 as conductive connection members. One end portion of the bonding wire 230 may be bonded to the chip pad 210, and another end portion of the bonding wire 230 may be bonded to an upper surface of the plating pattern 130 of a corresponding bond finger. For example, a thickness of the semiconductor chip 200 may be within a range of 40 μm to 120 μm. A thickness of the conductive adhesive film 220 may be within a range of 5 μm to 30 μm. The conductive adhesive film 220 may include a conductive die attach film.

A portion of the conductive adhesive film 220 attached on the chip mounting region MR may fill the first and second openings OR1, OR2. A portion of the conductive adhesive film 220 may be in contact with the first portion of the first wiring 121a exposed by the first opening OR1 and may be in contact with the first portion of the second wiring 121b exposed by the second opening OR2. Accordingly, the first wiring 121a and the second wiring 121b provided as the power wirings may be merged with each other by the conductive adhesive film 220. By merging the power wirings with each other, power integrity (PI) characteristics may be improved. In addition, since the first and second wirings 121a, 121b do not need to be merged with each other in another circuit layer below the uppermost insulating layer through a connection via, the circuit routing design may be facilitated.

In some embodiments, a portion of the conductive adhesive film 220 attached on the chip mounting region MR may be in contact with the first portion of the third wiring 122a exposed by the first opening OR1 and may be in contact with the first portion of the fourth wiring 122b exposed by the second opening OR2. Accordingly, the third wiring 122a and the fourth wiring 122b provided as the ground wirings may be merged with each other by the conductive adhesive film 220. By merging the ground wirings with each other, noise exposure of signals may be reduced, to thereby improve signal integrity (SI) characteristics. In addition, since the third and fourth wirings 122a, 122b do not need to be merged with each other in another circuit layer below the uppermost insulating layer through a connection via, the circuit routing design may be facilitated.

In example embodiments, the molding member 300 may be provided on the upper surface 102 of the package substrate 100 to cover the semiconductor chip 200 and the bonding wires 230. The molding member may include a thermosetting resin, for example, an epoxy mold compound (EMC).

In example embodiments, the lower substrate pads 134 for providing an electric signal may be formed on the lower surface 104 of the package substrate 100. The lower substrate pads 134 may be exposed by the lower protective layer 118. The external connection member 160 may be disposed on the lower substrate pad 134 of the package substrate 100 for electrical connection with an external device. For example, the external connection member 160 may be a solder ball. The semiconductor package 10 may be mounted on a module substrate (not illustrated) via the solder balls to constitute a memory module.

As mentioned above, the semiconductor package 10 may include the semiconductor chip 200 attached to the upper surface 102 of the package substrate 100 by the conductive adhesive film 220. The package substrate 100 may include the upper circuit wiring 113b including the first wiring 121a and the second wiring 121b extending on the upper insulating layer 110b, and the upper protective layer 116 covering the upper insulating layer 110b and having the first and second openings OR1, OR2 that expose the first portions of the first and second wirings 121a, 121b respectively.

The conductive adhesive film 220 may contact the first portions of the first and second wirings 121a, 121b exposed by the first and second openings OR1, OR2, respectively, so that the first wiring 121a and the second wiring 121b, which are provided as power wirings or ground wirings, can be merged with each other by the conductive adhesive film 220. That is, the first and second wirings 121a, 121b on the uppermost insulating layer 110b may be merged by the conductive adhesive film 220 attached to the package substrate 100 instead of another circuit layer inside the package substrate 100. Accordingly, electrical signal characteristics such as signal integrity (SI) and power integrity (PI) may be improved. Further, since the first and second wirings 121a, 121b do not need to be merged with each other in different circuit layers below the uppermost insulating layer through connection vias, the circuit routing may be easily designed.

Hereinafter, a method of manufacturing the semiconductor package of FIG. 1 will be described.

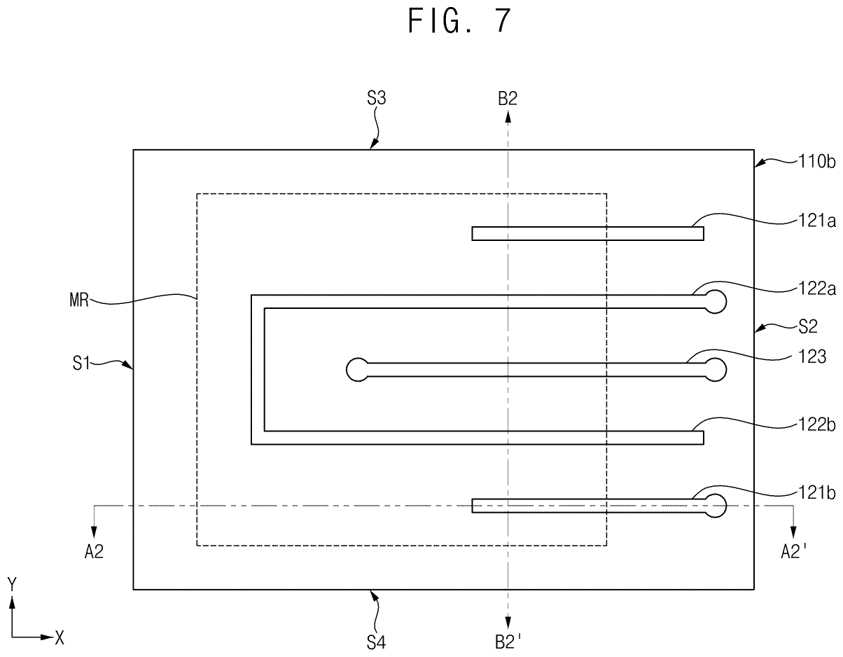

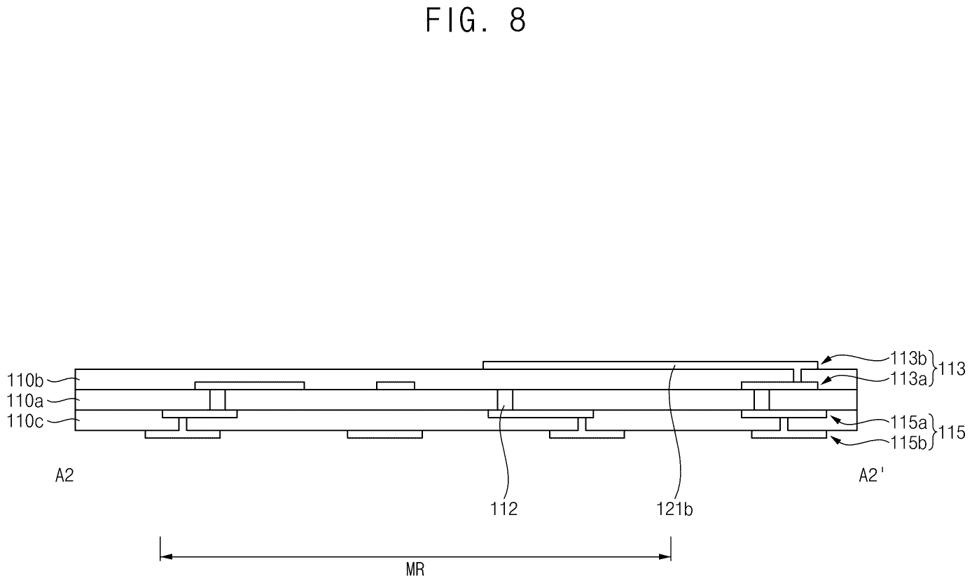

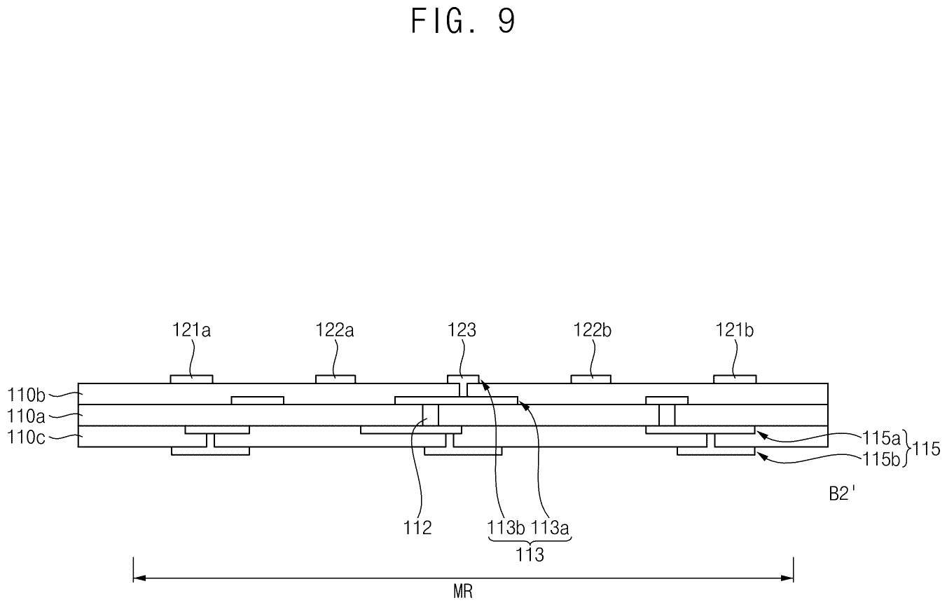

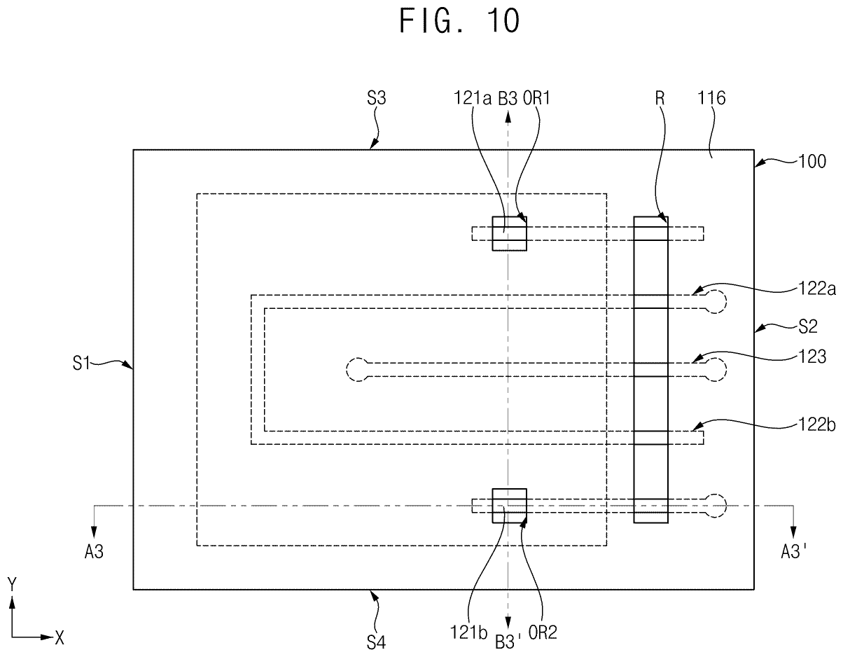

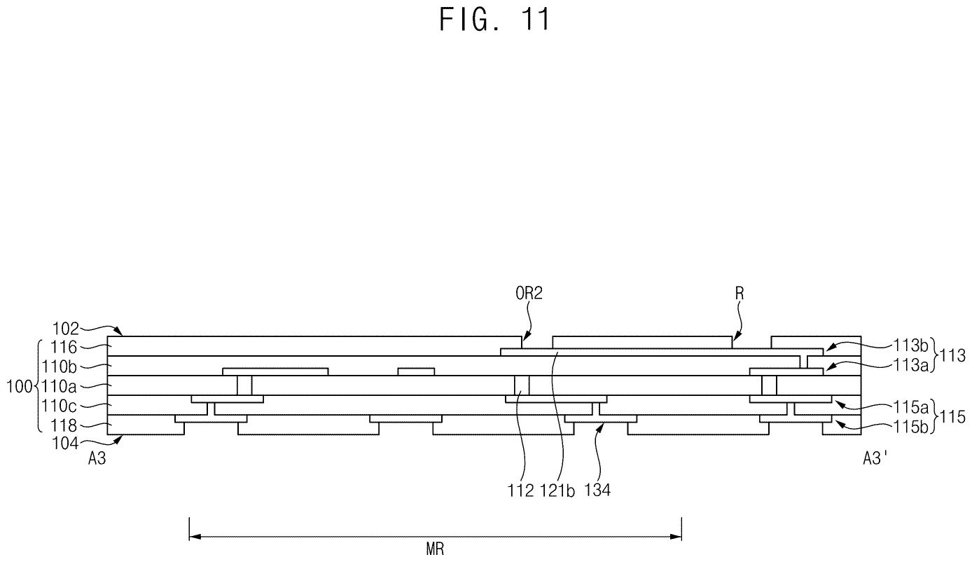

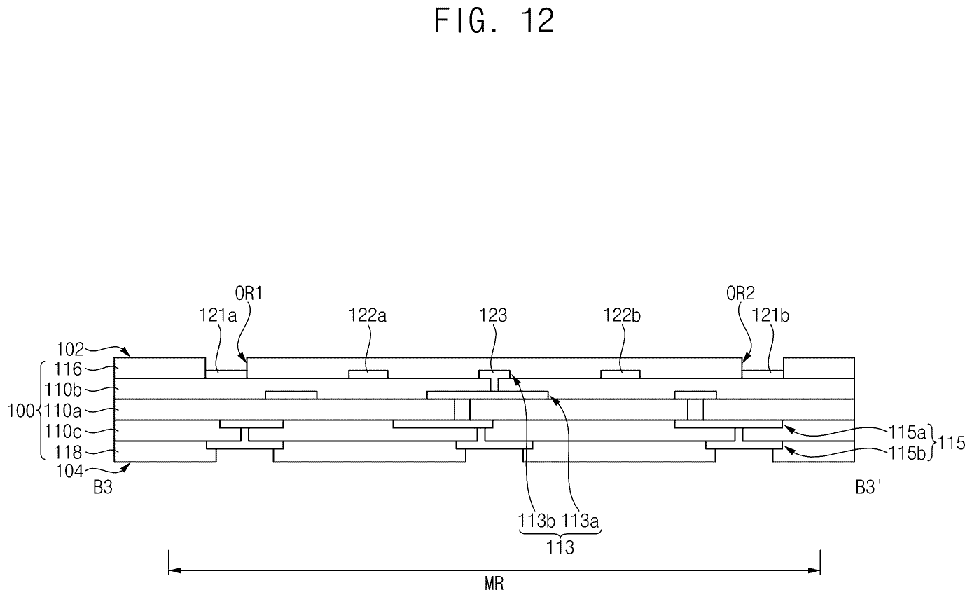

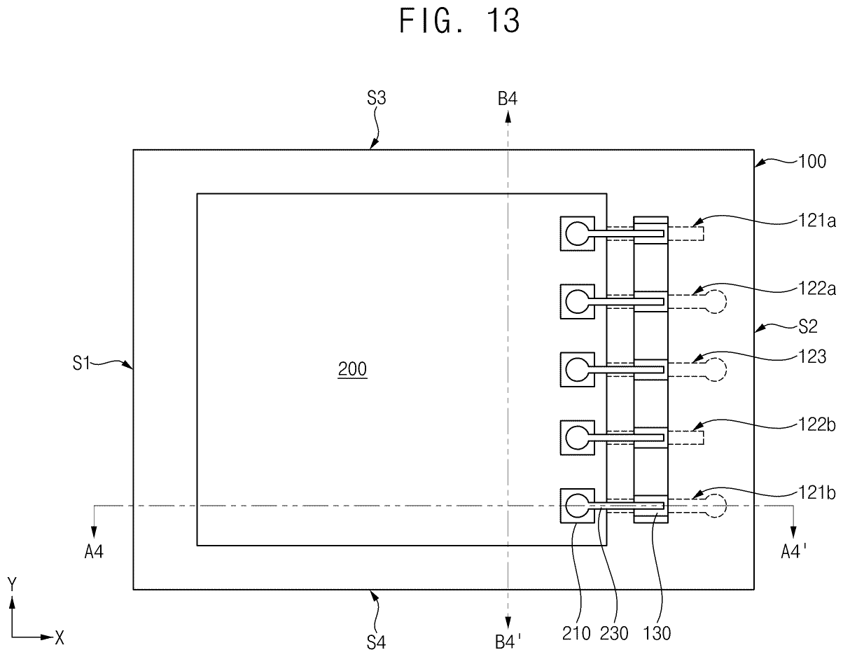

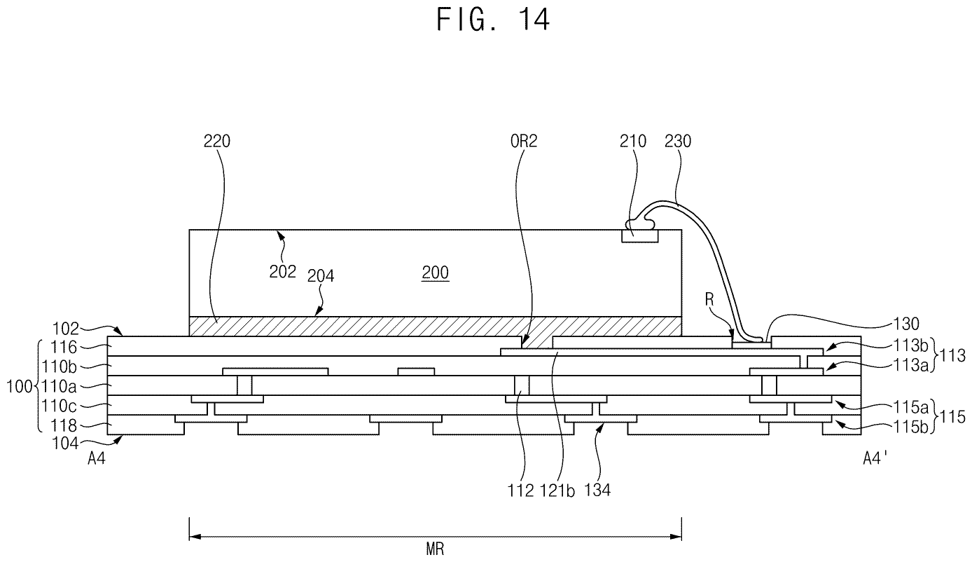

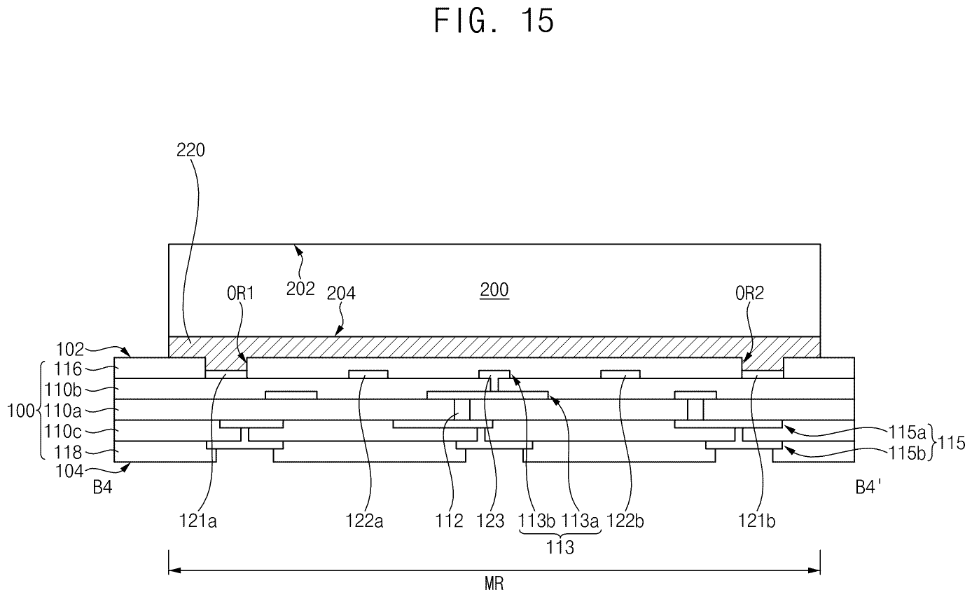

FIGS. 7 to 15 are views illustrating a method for manufacturing a semiconductor package in accordance with example embodiments. FIGS. 7, 10 and 13 are plan views illustrating a method of manufacturing a semiconductor package in accordance with example embodiments. FIG. 8 is a cross-sectional view taken along the line A2-A2′ in FIG. 7. FIG. 9 is a cross-sectional view taken along the line B2-B2′ in FIG. 7. FIG. 11 is a cross-sectional view taken along the line A3-A3′ in FIG. 10. FIG. 12 is a cross-sectional view taken along the line B3-B3′ in FIG. 10. FIG. 14 is a cross-sectional view taken along the line A4-A4′ in FIG. 13. FIG. 15 is a cross-sectional view taken along the line B4-B4′ in FIG. 13.

Referring to FIGS. 7 to 9, a plurality of stacked insulating layers 110a, 110b, 110c having circuit wirings 113, 115 therein may be provided.

In example embodiments, the plurality of stacked insulating layers 110a, 110b, 110c may be provided as a portion of a package substrate. The circuit wirings 113, 115 may include internal wirings as channels for electrical connection with a semiconductor chip as described below.

The plurality of stacked insulating layers 110a, 110b, 110c may include a first side portion S1 and a second side portion S2 extending in a direction parallel to a second direction (Y direction) and opposite each other, and a third side portion S3 and a fourth side portion S4 extending in a direction parallel to a first direction (X direction) perpendicular to the second direction and opposite each other.

The plurality of stacked insulating layers 110a, 110b, 110c may have a chip mounting region MR on which the semiconductor chip is to be mounted. As described below, the chip mounting region MR may be a region where the semiconductor chip is mounted. The chip mounting region MR may have a rectangular shape.

As illustrated in FIGS. 8 and 9, the wirings 113, 115 may be provided in the plurality of insulating layers 110a, 110b, 110c, respectively.

In particular, the package substrate may include a core layer 110a, an upper insulating layer 110b on an upper surface of the core layer 110a, and a lower insulating layer 110c on a lower surface of the core layer 110a. The upper insulating layer 110b may be provided as an uppermost insulating layer among the plurality of insulating layers 110a, 110b, 110c. The lower insulating layer 110c may be provided as a lowermost insulating layer among the plurality of insulating layers 110a, 110b, 110c.

The package substrate may include a plurality of through vias 112 penetrating the core layer 110a, first upper circuit wirings 113a on the upper surface of the core layer 110a, second upper circuit wirings 113b provided in the upper insulating layer 110b, first lower circuit wirings 115a on the lower surface of the core layer 110a, and second lower circuit wirings 115b provided in the lower insulating layer 110c.

For example, the insulating layer may include an insulating material such as a thermosetting resin such as epoxy resin or a thermoplastic resin such as polyimide. The insulating layer may include a resin impregnated in a core material such as organic fiber (glass fiber), for example, a prepreg, FR-4, BT (Bismaleimide Triazine), etc.

The first upper circuit wirings 113a, the second upper circuit wirings 113b, the first lower circuit wirings 115a, and the second lower circuit wirings 115b may include a data transmission pattern for exchanging electrical data with the semiconductor chip, a power pattern for transmitting driving power to the semiconductor chip, and a ground pattern for electrically grounding the semiconductor chip.

As illustrated in FIG. 7, the second upper circuit wirings 113b may extend on the uppermost insulating layer 110b among the plurality of insulating layers 110a, 110b, 110c. The second upper circuit wirings 113b may include a first wiring 121a and a second wiring 121b that are provided as power wirings through which a power signal is transmitted. The second upper circuit wirings 113b may include a third wiring 122a and a fourth wiring 122b that are provided as ground wirings through which a ground signal is transmitted. The second upper circuit wirings 113b may include a fifth wiring 123 that is provided as a signal wiring through which a data signal is transmitted.

The first wiring 121a and the second wiring 121b may extend in a direction parallel to the first direction (X direction) respectively. The fifth wiring 123 as at least one signal wiring may extend between the first wiring 121a and the second wiring 121b. The third wiring 122a and the fourth wiring 122b may extend in both sides of the fifth wiring 123 in a direction parallel to the extension direction of the fifth wiring 123, respectively. One end portion of the third wiring 122a and one end portion of the fourth wiring 122b may be merged with each other.

Although only a few wirings and circuit patterns are illustrated in the figures, the number, shape, and arrangement of the wirings and the circuit patterns are provided as examples, and it will be understood that example embodiments are not limited thereto.

As illustrated in FIGS. 10 to 12, an upper protective layer 116 may be formed on the upper surface of the upper insulating layer 110b to cover the second upper circuit wirings 113b and a lower protective layer 118 may be formed on the lower surface of the lower insulating layer 110c to cover the second lower circuit wirings 115b. An upper surface of the upper protective layer 116 may be provided as the upper surface 102 of the package substrate 100, and a lower surface of the lower protective layer 118 may be provided as a lower surface 104 of the package substrate 100.

In example embodiments, a solder resist layer may be formed on the upper surface of the upper insulating layer 110b, and exposure and development processes may be performed to form the upper protective layer 116 having a recess R and first and second openings OR1, OR2.

The first opening OR1 may expose a first portion of the first wiring 121a, and the second opening OR2 may expose a first portion of the second wiring 121b. Diameters (widths) of the first opening OR1 and the second opening OR2 may be greater or smaller than widths of the first wiring 121a and the second wiring 121b. In some embodiments, the first opening OR1 may expose a first portion of the third wiring 122a, and the second opening OR2 may expose a first portion of the fourth wiring 122b. In this case, one end portion of the third wiring 122a and one end portion of the fourth wiring 122b may not be merged but may be spaced apart from each other and may not be electrically connected to each other.

The recess R may extend in the second direction (Y direction) along one side of the chip mounting region MR. The recess R may have a rectangular shape. The recess R may expose a second portion of each of the first to fifth wirings 121a, 121b, 122a, 122b, 123. The second portions of the first to fifth wirings 121a, 121b, 122a, 122b, 123 may be spaced apart from each other in the second direction (Y direction) within the recess R. Each of the second portions of the first to fifth wirings 121a, 121b, 122a, 122b, 123 may extend within the recess R in the first direction (X direction). The second portions of the first to fifth wirings 121a, 121b, 122a, 122b, 123 may be exposed from a bottom surface of the recess R.

Similarly, the lower protective layer 118 may be formed on the lower surface of the lower insulating layer 110c to cover the second lower circuit wirings 115b. At least a portion of the second lower circuit wiring 115b exposed by the lower protective layer 118 may be provided as a lower substrate pad 134. The lower protective layer 118 may cover the entire lower surface of the insulating layers except for the lower substrate pads 134.

For example, thicknesses of the upper protective layer 116 and the lower protective layer 118 may be within a range of 5 μm to 30 μm. The thicknesses of the first to fifth wirings 121 a, 121b, 122a, 122b, 123 may be within a range of 5 μm to 30 μm. The upper protective layer 116 and the lower protective layer 118 may include a photosensitive resin such as photo epoxy, and a photosensitive polymer such as photosensitive polyimide (PSPI), photo solder resist (PSR), etc.

Referring to FIGS. 13 to 15, a semiconductor chip 200 may be mounted on the package substrate 100.

In example embodiments, at least one semiconductor chip 200 may be placed on the package substrate 100. The semiconductor chip 200 may be attached to the upper protective layer 116 of the package substrate 100 by a conductive adhesive film 220. The semiconductor chip 200 may be arranged such that a surface 204 opposite to a front surface 202 on which chip pads 210 are formed, that is, an active surface, faces the package substrate 100. The semiconductor chip 200 may have a rectangular shape with four sides when viewed in plan view. The chip pads 210 may be arranged on the front surface 202 of the first semiconductor chip 200 to be spaced apart from each other along one side thereof. For example, a thickness of the semiconductor chip 200 may be within a range of 40 μm to 120 μm. A thickness of the conductive adhesive film 220 may be within a range of 3 μm to 60 μm. The conductive adhesive film 220 may include a conductive die attach film.

A portion of the conductive adhesive film 220 attached on the chip mounting region MR may fill the first and second openings OR1, OR2. A portion of the conductive adhesive film 220 may be brought into contact with the first portion of the first wiring 121a exposed by the first opening OR1 and may be brought into contact with the first portion of the second wiring 121b exposed by the second opening OR2. Accordingly, the first wiring 121a and the second wiring 121b provided as the power wirings may be merged with each other by the conductive adhesive film 220. By merging the power wirings with each other, power integrity (PI) characteristics may be improved. In addition, since the first and second wirings 121a, 121b do not need to be merged with each other in another circuit layer below the uppermost insulating layer through a connection via, the circuit routing design may be facilitated.

In some embodiments, a portion of the conductive adhesive film 220 attached on the chip mounting region MR may be brought into contact with the first portion of the third wiring 122a exposed by the first opening OR1 and may be brought into contact with the first portion of the fourth wiring 122b exposed by the second opening OR2. Accordingly, the third wiring 122a and the fourth wiring 122b provided as the ground wirings may be merged with each other by the conductive adhesive film 220. By merging the ground wirings with each other, noise exposure of signals may be reduced, to thereby improve signal integrity (SI) characteristics. In addition, since the third and fourth wirings 122a, 122b do not need to be merged with each other in another circuit layer below the uppermost insulating layer through a connection via, the circuit routing design may be facilitated.

In example embodiments, a plating process may be performed to form a plating pattern 130 on the second portion of each of the first to fifth wirings 121a, 121b, 122a, 122b, 123 exposed by the recess R. For example, a first plating process may be performed to form a first plating pattern, and a second plating process may be performed to form a second plating pattern on the first plating pattern. The plating pattern 130 may include the first plating pattern and the second plating pattern on the first plating pattern. The first plating pattern may include nickel (Ni), and the second plating pattern may include gold (Au).

The plating pattern 130 on the second portion of each of the first to fifth wirings 121a, 121b, 122a, 122b, 123 within the recess R may serve as a bond finger that provides a plane on which the bonding wire is bonded.

Then, a wire bonding process may be performed to connect the chip pads 210 of the semiconductor chip 200 to the bond fingers of a package substrate 100. The chip pads 210 of the semiconductor chip 200 may be connected to the plating patterns 130 as the bond fingers by bonding wires 230 as conductive connection members.

Then, a molding member (300, see FIG. 2) may be formed on the upper surface of the package substrate 100 to cover the semiconductor chip 200. The molding member may include a thermosetting resin, for example, an epoxy mold compound (EMC).

Then, external connection members (160, see FIG. 2) may be formed on the lower substrate pads 134 on the lower surface of the package substrate 100 to complete the semiconductor package 10 of FIG. 1.

For example, the external connection members may include solder balls. The external connection members may be formed on the lower substrate pads 130 of the package substrate 100 by a solder ball attach process, respectively.

The semiconductor package may include a semiconductor device such as a logic device or a memory device. The semiconductor package may include a logic device such as a central processing unit (CPU), a main processing units (MPU), or an application processor (AP), or the like, and a volatile memory device such as a DRAM device, an HBM device, or a non-volatile memory device such as a flash memory device, a PRAM device, an MRAM device, an ReRAM device, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a package substrate having a chip mounting region, the package substrate including at least one insulating layer, upper circuit wirings having a first wiring and a second wiring that respectively extend on the at least one insulating layer, and an upper protective layer covering the upper circuit wirings on the at least one insulating layer and having a first opening and a second opening that respectively expose first portions of the first wiring and the second wiring;
a semiconductor chip disposed on the chip mounting region of the package substrate and having a plurality of chip pads; and
a conductive adhesive film attaching the semiconductor chip to the package substrate, and disposed in the first opening and the second opening to contact the first portions of the first wiring and the second wiring, respectively, to electrically connect the first wiring and the second wiring to each other.

2. The semiconductor package of claim 1, wherein the conductive adhesive film includes a conductive die attach film.

3. The semiconductor package of claim 1, wherein the conductive adhesive film has a thickness within a range of 3 μm to 60 μm.

4. The semiconductor package of claim 1, wherein the first wiring and the second wiring are configured as power wirings through which a power signal is transmitted.

5. The semiconductor package of claim 1, wherein the first wiring and the second wiring are configured as ground wirings through which a ground signal is transmitted.

6. The semiconductor package of claim 1, wherein the upper protective layer includes photosensitive polyimide.

7. The semiconductor package of claim 1, wherein the upper circuit wirings further include at least one signal wiring that extends between the first wiring and the second wiring on the at least one insulating layer.

8. The semiconductor package of claim 1, wherein the upper protective layer has a recess that exposes a second portion of at least one of the first wiring and the second wiring,
the semiconductor package further comprising:
a plating pattern on the second portion of the at least one of the first wiring and th second wiring exposed within the recess; and
a bonding wire electrically connecting a corresponding one of the plurality of chip pads and the plating pattern.

9. The semiconductor package of claim 1, wherein the plurality of chip pads are disposed on a first surface of the semiconductor chip, and the conductive adhesive film is attached to a second surface of the semiconductor chip opposite to the first surface.

10. The semiconductor package of claim 1, further comprising:
a molding member covering the semiconductor chip on the upper protective layer.

11. A semiconductor package, comprising:
a plurality of insulating layers having a chip mounting region;
upper circuit wirings having a first wiring and a second wiring that respectively extend on an uppermost insulating layer among the plurality of insulating layers and at least one signal wiring that extends between the first wiring and the second wiring;
an upper protective layer covering the upper circuit wirings on the uppermost insulating layer and having a first opening and a second opening that respectively expose first portions of the first wiring and the second wiring within the chip mounting region, and a recess that expose a portion of the at least one signal wiring outside the chip mounting region;
a plating pattern disposed on the portion of the at least one signal wiring exposed within the recess;
a semiconductor chip disposed within the chip mounting region on the upper protective layer and having a plurality of chip pads;
a conductive adhesive film within the chip mounting region and attaching the semiconductor chip to the uppermost insulating layer, wherein the conductive adhesive film is disposed in the first opening and the second opening to contact the first portions of the first wiring and the second wiring, respectively, to electrically connect the first wiring and the second wiring to each other; and
a bonding wire electrically connecting one chip pad of the plurality of chip pads to the plating pattern.

12. The semiconductor package claim 11, wherein the conductive adhesive film includes a conductive die attach film.

13. The semiconductor package of claim 11, wherein the conductive adhesive film has a thickness within a range of 3 μm to 60 μm.

14. The semiconductor package of claim 11, wherein the first wiring and the second wiring are configured as power wirings through which a power signal is transmitted.

15. The semiconductor package of claim 11, wherein the first wiring and the second wiring are configured as ground wirings through which a ground signal is transmitted.

16. The semiconductor package of claim 11, wherein the upper protective layer includes photosensitive polyimide.

17. The semiconductor package of claim 11, wherein the recess of the upper protective layer exposes second portions of the first wiring and the second wiring,
the semiconductor package further comprising:
plating patterns disposed on the second portions of the first wiring and the second wiring exposed within the recess; and
bonding wires electrically connecting corresponding ones of the plurality of chip pads and the plating patterns, respectively.

18. The semiconductor package of claim 11, wherein the semiconductor chip is arranged such that a second surface, opposite to a first surface on which the chip pads are disposed, faces the uppermost insulating layer.

19. The semiconductor package of claim 11, further comprising:
a molding member covering the semiconductor chip on the upper protective layer.

20. A semiconductor package, comprising:
a package substrate having a chip mounting region, the package substrate including a plurality of insulating layers, upper circuit wirings having a first wiring and a second wiring that respectively extend on an uppermost insulating layer among the plurality of insulating layers and at least one signal wiring that extends between the first wiring and the second wiring, and an upper protective layer covering the uppermost insulating layer and having first and second openings that expose first portions of the first and second wirings, respectively, and a recess that expose second portions of the first and second wirings, respectively;
plating patterns disposed on the second portions of the first and second wirings exposed within the recess;
a semiconductor chip on the upper protective layer and having a plurality of chip pads;
a conductive adhesive film within the chip mounting region and attaching the semiconductor chip to the package substrate, wherein the conductive adhesive film is disposed in the first opening and the second opening to contact the first portions of the first wiring and the second wiring, respectively, to electrically connect the first wiring and the second wiring to each other; and
bonding wires electrically connecting corresponding ones of the plurality of chip pads to the plating patterns.
